(19) United States
(12) Patent Application Publication
(10) Pub. No.: US 2023/0282699 A1
(43) Pub. Date: Sep. 7, 2023

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Tefu Yeh, Kaohsiung City (TW); Ming-Chi Huang, Hsinchu County (TW); Jo-Chun Hung, Hsinchu City (TW); Ying-Liang Chuang, Hsinchu County (TW); Ming-Hsi Yeh, Hsinchu (TW); Kuo-Bin Huang, Hsinchu County (TW)

(73) Assignee: Taiwan Semiconductor Manufacturing Company, Ltd., Hsinchu (TW)

(21) Appl. No.: 17/683,372

(22) Filed: Mar. 1, 2022

(51) Int. Cl. H01L 29/06; H01L 29/423; H01L 29/786; H01L 29/66; H01L 21/762

(52) U.S. Cl. CPC H01L 29/0665; H01L 29/42392; H01L 29/78618; H01L 29/78696; H01L 29/66742; H01L 29/66545; H01L 21/76224

(57) ABSTRACT

A semiconductor device structure and a manufacturing method thereof are provided. The structure includes a substrate having a first region and a second region, first and second semiconductor channel sheets, first and second gate structure and source and drain regions. The first and second semiconductor channel sheets are disposed over the substrate and respectively in the first region and the second region. The first semiconductor channel sheets have a first channel width shorter than a second channel width of the second semiconductor channel sheets. The first and second gate structures are disposed over and laterally surrounding the first and second semiconductor channel sheets respectively. The first gate structure includes a first gate dielectric layer and a first metallic layer. The second gate structure includes a second gate dielectric layer and a second metallic layer. The source and drain regions are located beside the first and second semiconductor channel sheets. Tops of the first and second metallic layers are located at a same horizontal level.

### BACKGROUND

Continuously scaling down and high integration density of semiconductor devices have increased the complexity of semiconductor manufacturing processes.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 are schematic views of various stages in a manufacturing method of a semiconductor device in accordance with some embodiments of the disclosure.

FIG. 7 to FIG. 12 are schematic views of various stages in a manufacturing method of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

It should be appreciated that the following embodiment(s) of the present disclosure provides applicable concepts that can be embodied in a wide variety of specific contexts. The embodiments are intended to provide further explanations but are not used to limit the scope of the present disclosure. The specific embodiment(s) described herein is related to a structure containing one or more semiconductor devices, and is not intended to limit the scope of the present disclosure. Embodiments of the present disclosure describe the exemplary manufacturing process of the structure(s) formed with one or more semiconductor devices such as transistors and the integrated structures fabricated there-from. Certain embodiments of the present disclosure are related to the structures including semiconductor transistors and/or other elements. The substrates and/or wafers may include one or more types of integrated circuits or electronic components therein. The semiconductor device(s) may be formed on a bulk semiconductor substrate or a silicon/germanium-on-insulator substrate.

The present disclosure describes semiconductor devices, such as field-effect transistors (FETs), such as planar FETs, fin-type FETs (FinFETs), or gate all around (GAA) transistors. The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

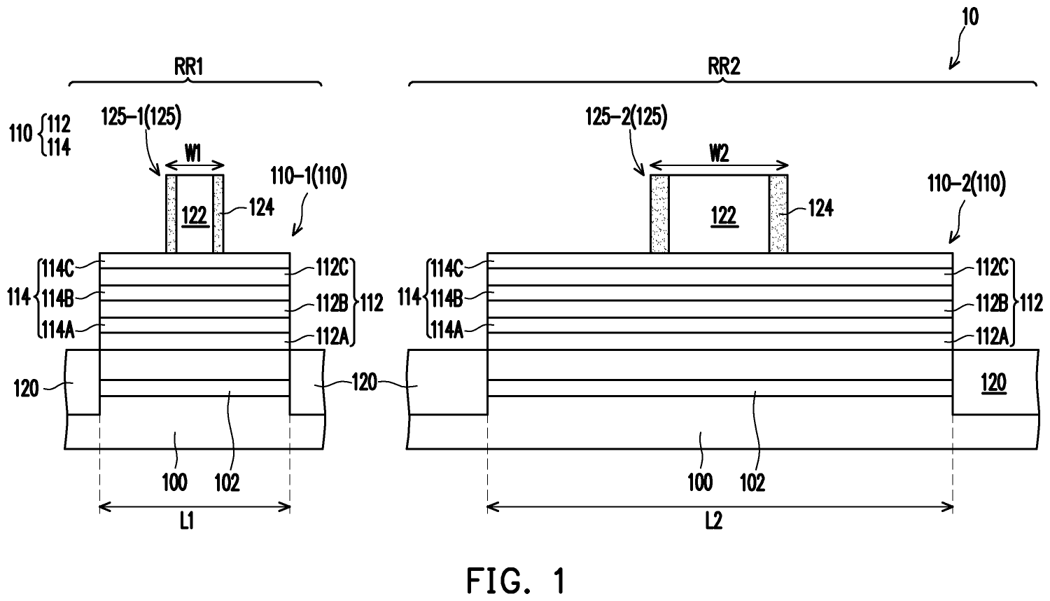

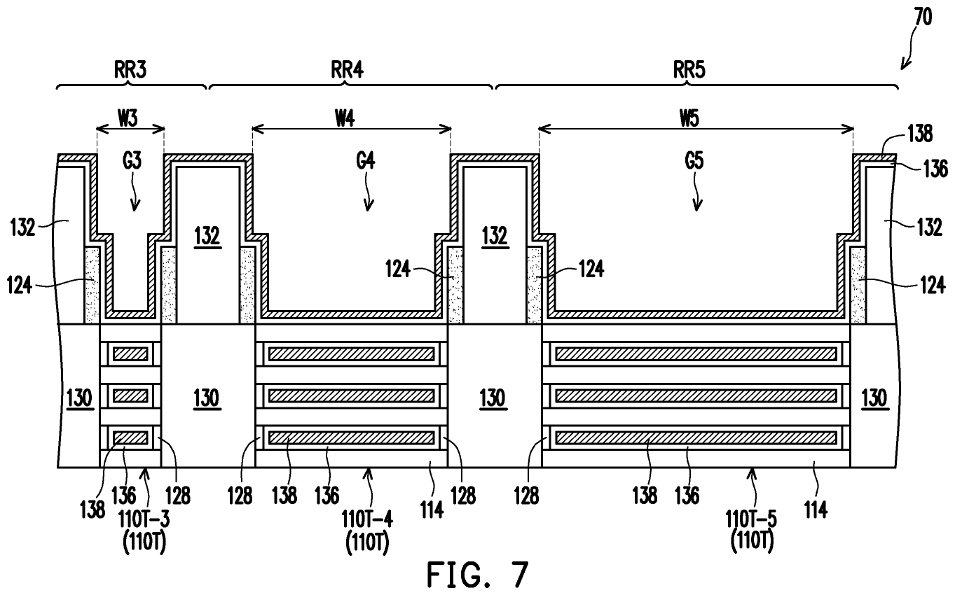

FIG. 1 to FIG. 6 are schematic views of various stages in a manufacturing method of semiconductor devices in accordance with some embodiments of the disclosure. FIG. 7 to FIG. 12 are schematic views of various stages in a manufacturing method of semiconductor devices in accordance with some embodiments of the disclosure. From FIG. 1 through FIG. 6, schematic cross-section views of semiconductor devices in a first region RR1 and a second region RR2 of the structure at successive intermediate stages of processing are shown. From FIG. 7 through FIG. 12, schematic cross-section views of semiconductor devices in a third region RR3, a fourth region RR4 and a fifth region RR5 at successive intermediate stages of processing are shown. Particularly, FIG. 1 to FIG. 6 and FIG. 7 to FIG. 12 illustrate exemplary manufacturing processes for forming gate all around (GAA) transistors. Other process steps and combinations of process steps can be utilized without departing from the scope of the present disclosure.

Referring to FIG. 1, in some embodiments, a structure 10 having a substrate 100 with a material layer 102 embedded therein is provided. As shown in FIG. 1, in some embodiments, the structure 10 includes a first region RR1 and a second region RR2. In some embodiments, the first region RR1 and the second region RR2 may be adjacent to each other. In some embodiments, the first region RR1 and the second region RR2 may be spaced apart with other regions located there-between. In some embodiments, the first region RR1 and the second region RR2 are located in the device region. In some embodiments, the first region RR1 is a high density region having devices of smaller critical dimensions and higher integration density, while the second region RR2 is a low density region having devices of larger critical dimensions and lower integration density. In some embodiments, the first region RR1 is a core region, while the second region RR2 is a peripheral region. From FIG. 1 to FIG. 6, only portions of the first region RR1 and the second region RR2 are shown for illustration purposes.

Referring to FIG. 1, in some embodiments, the substrate 100 includes a semiconductor substrate. In one embodiment, the substrate 100 comprises a bulk semiconductor substrate such as a crystalline silicon substrate, and may be doped (e.g., p-type or n-type semiconductor substrate) or undoped. In one embodiment, the substrate 100 comprises a silicon-on-insulator substrate or a germanium-on-insulator substrate. In certain embodiments, the substrate 100 includes one or more doped regions or various types of doped regions, depending on design requirements. In some embodiments, the doped regions are doped with p-type and/or n-type dopants. For example, the p-type dopants are boron, indium, aluminum, or gallium, and the n-type dopants are phosphorus or arsenic. In some embodiments, the substrate 100 includes a semiconductor substrate made of other suitable elemental semiconductor, such as diamond or germanium; a suitable compound semiconductor, such as gallium arsenide (GaAs), silicon carbide (SiC), indium arsenide (InAs), or indium phosphide (InP); or a suitable alloy semiconductor, such as silicon-germanium (SiGe), gallium arsenic phosphide (GaAsP), or gallium indium phosphide (GaInP). In some embodiments, the substrate 100 includes an oxide semiconductor material such as indium tin oxide (ITO). In some embodiments, the material layer 102 includes a semiconductor material different from the material of the substrate 100. In some embodiments, the layer 102 is optional and may be omitted. It is understood that different types of substrates, such as single-layer, multi-layered, or gradient substrates may be used.

In FIG. 1, in some embodiments, two or more fin stacks 110 of multiple sheets are formed over the substrate 100 respectively in the first region RR1 and the second region RR2. Either in the first region RR1 or in the second region RR2, each fin stack 110 includes alternating layers of first semiconductor layers 112A-112C (collectively referred to as first semiconductor layers 112) and second semiconductor layers 114A-114C (collectively referred to as second semiconductor layers 114). In some embodiments, the first semiconductor layers 112 is formed of a first semiconductor material, the second semiconductor layers 114 is formed of a second semiconductor material, and the second semiconductor material is different from the first semiconductor material. For example, the first or second semiconductor material may include one or more selected from silicon, germanium, SiC, SiGe, GaAs, InSb, GaP, GaSb, InAlAs, InGaAs, GaSbP, GaAsSb or InP. In some embodiments, the first semiconductor layers 112 may include silicon germanium (SiGe) or the like, and the second semiconductor layers 114 may include silicon, silicon carbide, or the like. In at least one embodiment, second semiconductor layers 114 are of the same semiconductor material as the substrate 100. In a non-limiting example described herein, the second semiconductor layers 114 and the substrate 100 include silicon.

For example, the fin stacks 110 may be formed by performing alternating epitaxial growth processes, including performing first epitaxial growth processes to form first semiconductor material layers (not shown) and performing second epitaxial growth processes to form second semiconductor material layers (not shown) in alternation, and then patterning the first and second semiconductor material layers into the first and second semiconductor layers 112 and 114 of the fin stacks 110 and patterning the substrate 100 to form trenches in the substrate 100, and later an insulating material is filled into the trenches to form isolation structures 120. In some embodiments, the formation of the first or second semiconductor layer 112 or 114 may include one or more processes selected from chemical vapor deposition (CVD), atomic layer deposition (ALD), vapor phase epitaxy (VPE), molecular beam epitaxy (MBE), or the like. In some embodiments, the patterning may include one or more suitable etching processes, such as reactive ion etch (RIE), neutral beam etch (NBE), or a combination thereof. In some embodiments, the etching processes include anisotropic etching processes. In some embodiments, the isolation structures 120 are trench isolation structures and the insulating material filled in the trenches may include silicon oxide, silicon nitride, silicon carbon nitride (SiCN), silicon oxycarbon nitride (SiOCN), silicon germanium oxide or other suitable insulating materials.

In some embodiments, referring to FIG. 1, each fin stack 110 includes the first semiconductor layers 112A-112C (i.e. first semiconductor sheets 112) and second semiconductor layers 114A-114C (i.e. second semiconductor sheets 114) positioned between the first semiconductor layers 112A-112C. In some embodiments, the fin stack 110-1 in the first region RR1 has a length L1 (defined by the isolation structures 120) smaller than a length L2 (defined by the isolation structures 120) of the fin stack 110-2 in the second region RR2. It is understood that the alternating epitaxial growth processes are performed until a selected number of semiconductor sheets have been formed, and the number of the semiconductor sheets is not limited by the exemplary embodiments and figures provided herein. For example, each fin stack 110 may include six to twenty semiconductor sheets. Other numbers of semiconductor sheets can be utilized without departing from the scope of the present disclosure. In some embodiments, the semiconductor sheets are formed on the substrate 100 or over the substrate 100 with material layers there-between.

Referring to FIG. 1, dummy gate structures 125 are formed on the fin stacks 110. In some embodiments, the dummy gate structures 125 (including the dummy gate structures 125-1 and 125-2) include dummy gates 122 and spacers 124 formed on the sides of the dummy gates 124. For example, the dummy gate 122 may be formed by depositing a polysilicon layer, and then patterned through standard photolithography processes along with the photoresist mask, a hard mask, or other types of masks. Later, gate spacers 124 along the sides of the dummy gates 122 are formed by deposition and then etching. In one example, the dummy gate 122 includes polysilicon, and the gate spacers 124 include SiN or SiCON. In certain embodiments, the gate spacers 124 may be single-layered or multi-layered structures.

In some embodiments, the dummy gate structure 125-1 formed on the fin stack 110-1 in the first region RR1 has a gate width W1 smaller than a gate width W2 of the dummy gate structure 125-2 formed on the fin stack 110-2 in the second region RR2. In some embodiments, the gate width W1 of the narrower dummy gate structure 125-1 ranges from about 5 nm to about 20 nm, and the gate width W2 of the wider dummy gate structure 125-2 ranges from about 35 nm to about 125 nm. In one embodiment, the gate width W1 of the narrower dummy gate structure 125-1 is about 10 nm, and the gate width W2 of the wider dummy gate structure 125-2 is about 100 nm.

In FIG. 1, in some embodiments, the fin stacks 110 and the dummy gate structures 125 are shown to have substantially vertical sidewalls. When the fin stacks 110 have substantially vertical sidewalls, the first semiconductor layers 112 and the second semiconductor layers 114 may have substantially the same length/width. However, it is understood that the fin stacks 110 may have tapered sidewalls, such that a length/width of each of the first semiconductor layers 112 and the second semiconductor layers 114 may continuously increase in a direction towards the substrate 100. In some embodiments, the dummy gate structures 125 have slightly tapered or slant sidewalls.

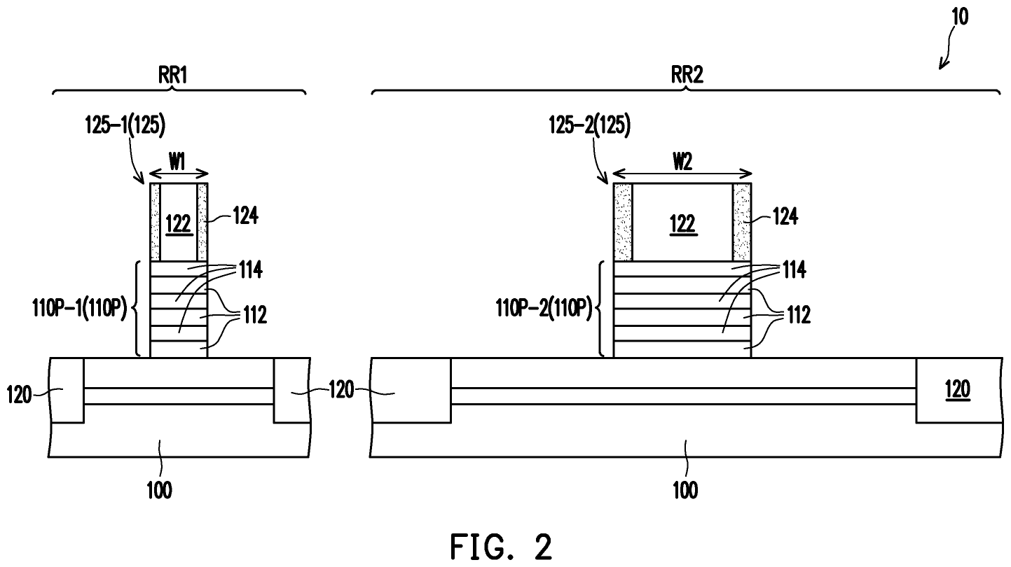

In FIG. 2, using the dummy gate structures 125 on the fin stacks as the masks, the fin stacks 110 (including the fin stack 110-1 in the first region RR1 and the fin stack 110-2 in the second region RR2) are patterned into the stacks 110P. That is, using the dummy gates 122 and the gate spacers 124 together as masks, the first semiconductor layers 112 and the second semiconductor layers 114 in the respective stacks 110 are etched. In some embodiments, the fin stack 110-1 in the first region RR1 is patterned into the stack 110P-1 and the fin stack 110-2 in the second region RR2 is patterned into the stacks 110P-2. In some embodiments, the etching process includes one or more anisotropic etching processes. In one embodiment, the stack 110P-1 has the substantially the same width W1 as the above dummy gate structure 125-1, while the stack 110P-2 has the substantially the same width W2 as the above dummy gate structure 125-2.

For certain specific etching processes such as the lateral etching process, due to high etch selectivity between the first semiconductor material(s) and the second semiconductor material(s), the first semiconductor layers 112 of the first semiconductor material may be etched or removed without significantly removing the second semiconductor layers 114 of the second semiconductor material. In some embodiments, the first semiconductor layers 112 are sacrificial layers that will later be removed, and the patterned second semiconductor layers 114 of the patterned stacks 110P are to form channel regions of the transistors. It is designed that there is high etch selectivity among the first and second semiconductor materials, so that one semiconductor material can be removed without significantly removing the other semiconductor material.

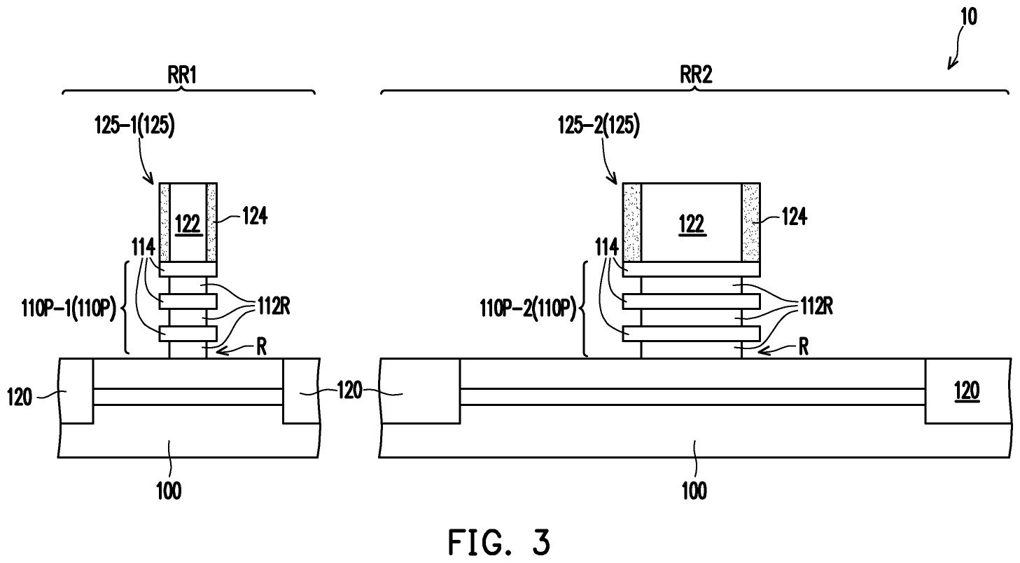

In FIG. 3, the first semiconductor layers 112 are laterally etched to form recessed first semiconductor layers 112R with side recesses R. In FIG. 3, the etching process has been performed to laterally recess the first semiconductor layers 112 (i.e. the sacrificial semiconductor layers) with respect to the second semiconductor layers 114. In some embodiments, the lateral etching process may include a wet etching process by using a chemical bath with etchant(s) that selectively etches the first semiconductor layers 112 (i.e. the sacrificial semiconductor layers) with respect to the second semiconductor layers 114. For example, the wet etching process is timed so that the first semiconductor layers 112 are recessed but not entirely removed. The formed recesses R are utilized to enable the formation of lateral spacers at opposite sides of the recessed first semiconductor layers 112R and between the second semiconductor layers 114.

In one embodiment, the first semiconductor layers 112 include SiGe, while the second semiconductor layers 114 include silicon or silicon carbide. Such material difference allows the lateral etching process to recess the first semiconductor layers 112 to become the recessed first semiconductor layers 112R without significantly etching the second semiconductor layers 114. In FIG. 3, the remained second semiconductor layers 114, function as channel regions, have substantially the same width (i.e. channel width) as the width of the above dummy gate structure 125. That is, the second semiconductor layers 114 of the stack 110P-1 in the first region RR1 has the channel width the same as the gate width W1 of the dummy gate structure 125-1, and the second semiconductor layers 114 of the stack 110P-2 in the second region RR2 has the channel width the same as the gate width W2 of the dummy gate structure 125-2.

In some embodiments, as the width W2 is larger than the width W1, the first region RR1 may be referred to as a short channel region while the second region RR2 may be referred to as a long channel region.

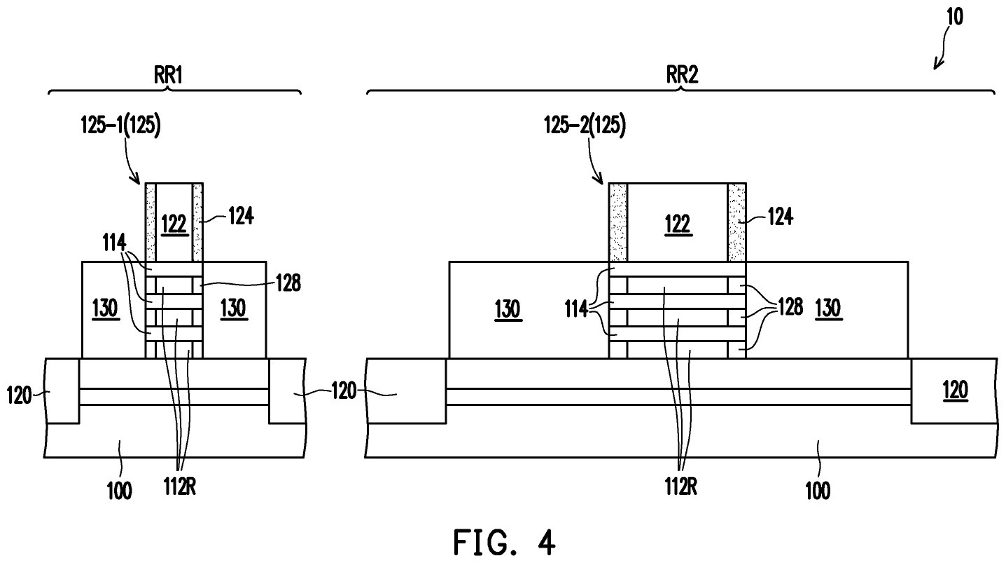

In FIG. 4, in some embodiments, lateral spacers 128 are formed in the recesses R at opposite sides of the recessed first semiconductor layers 112R and between the second semiconductor layers 114. In some embodiments, the formation of the lateral spacers 128 includes depositing a spacer material such as silicon nitride by an ALD process, a CVD process, or other suitable processes into the recesses R and then performing at least one etching process to remove the extra spacer material by utilizing the gate spacers 124 as masks. In FIG. 4, the lateral spacers 128 are located directly below the gate spacers 124, and the outer sidewalls of the lateral spacers 128 and the gate spacers 124 are vertically aligned.

Referring to FIG. 4, source and drain regions 130 are formed beside the stacks 110P. In some embodiments, the source and drain regions 130 are epitaxy source and drain portions including crystalline materials exerting a tensile strain in the channel regions. In some embodiments, for N-type transistors, the source and drain regions 130 may include materials such as silicon, SiC, SiCP, SiP, or the like. In some embodiments, for P-type transistors, the source and drain regions 130 include materials such as SiGe, SiGeB, Ge, GeSn, or the like. The source and drain regions 130 may have facets and/or have surfaces raised from the top surfaces of the isolation structures 120 or substrate 100. In some embodiments, the source and drain regions 130 are grown epitaxially from the second semiconductor layers 114. In some embodiments, the source and drain regions 130 are epitaxially grown from the substrate 100. The source and drain regions 130 may be further doped with N-type dopants for N-type transistors. The source and drain regions 130 may be doped with P-type dopants for P-type transistors. The doping can be performed in-situ during the epitaxial growth.

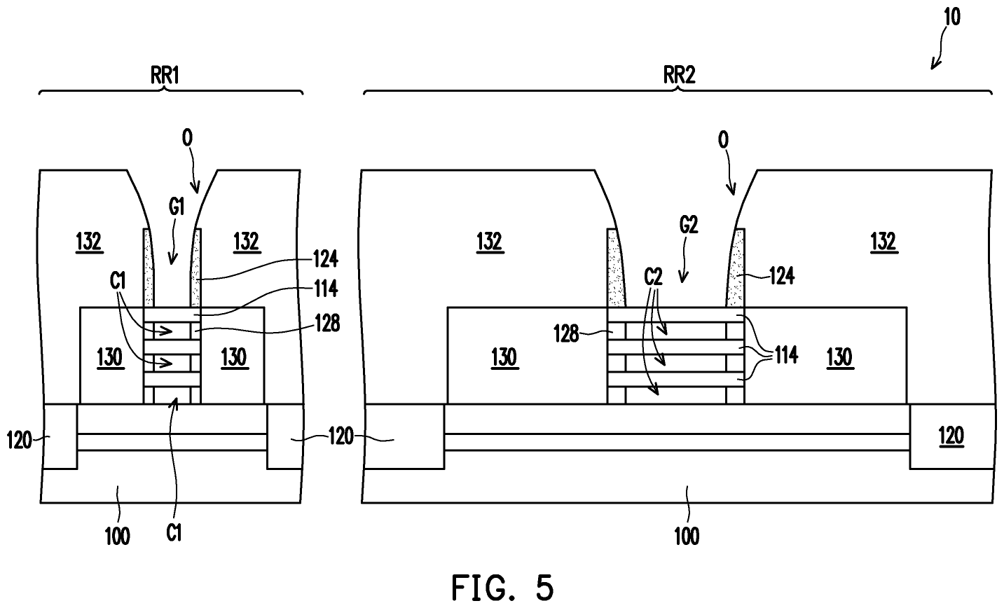

Referring to FIG. 4 and FIG. 5, in some embodiments, an interlayer dielectric (ILD) layer 132 is formed over the substrate 100 covering the source and drain regions 130 and on the isolation structures 120. In some embodiments, the interlayer dielectric layer 132 is formed with openings O so that the interlayer dielectric layer 132 covers the gate spacers 124 but exposes the dummy gates 122. In some embodiments, the interlayer dielectric layer 132 includes silicon oxide, and the interlayer dielectric layer 132 is formed by CVD, ALD, or other suitable deposition processes. Later, using the interlayer dielectric layer 132 and the gate spacers 124 in the first and second regions RR1 and RR2 as masks, the exposed dummy gates 122 and the recessed first semiconductor layers 112R in the first and second regions RR1 and RR2 are removed. Herein, the first semiconductor layers are removed and replaced by later formed layers and may be referred to as replaceable semiconductor layers or sheets.

In some embodiments, the dummy gates 122 in the first and second regions RR1 and RR2 are removed in a first etching step, and the recessed first semiconductor layers in the first and second regions RR1 and RR2 are removed in a second etching step. The first etching step selectively etches the dummy gates 122 with respect to the gate spacers 124, while the second etching step selectively etches the corresponding first semiconductor layers with respect to the material of the lateral spacers 128. In some alternative embodiments, a single etching process is performed to remove both the dummy gates 122 and the recessed first semiconductor layers 112R.

Referring to FIG. 5, in some embodiments, the removal of the exposed dummy gate 122 in the first region RR1 leaves a gate trench G1 between the gate spacers 124, and the removal of the exposed dummy gate 122 in the second region RR2 leaves a gate trench G2 between the gate spacers 124. The gate trench G1 or G2 corresponds to the location of a gate electrode of the to-be-formed transistor(s). Referring to FIG. 5, in some embodiments, the removal of the recessed first semiconductor layers 112R in the first region RR1 leaves cavities C1 between the second semiconductor layers 114, and the removal of the recessed first semiconductor layers 112R in the second region RR2 leaves cavities C2 between the second semiconductor layers 114.

Based on the layout design, the gate trench and the below cavities may be adjoining and contiguous with each other.

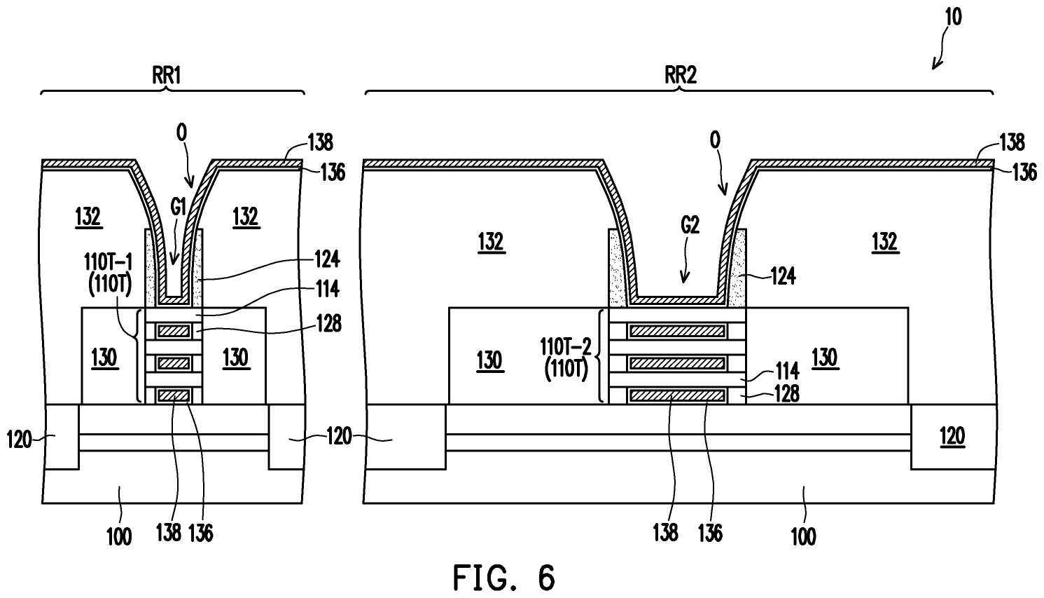

Referring to FIG. 6, a high-k dielectric layer 136 is formed over the substrate 100 covering the interlayer dielectric layer 132 in the first and second regions RR1 and RR2. In some embodiments, the high-k dielectric layer 136 conformally covers the gate trenches G1 and G2 and the cavities C1 and C1 in the first and second regions RR1 and RR2. In some embodiments, the high-k dielectric layer 136 is deposited directly on and all over the exposed surfaces of the gate trenches G1 and G2 and deposited directly on the exposed surfaces of the cavities C1 and C2. That is, the exposed surfaces of the second semiconductor layers (i.e. semiconductor nanosheets) 114 are fully covered by the high-k dielectric layer 136. In some embodiments, the second semiconductor layers 114 have the shape like sheets (with a larger dimension) or wires (with a smaller dimension) and may be referred as nanosheets or nanowires. Referring to FIG. 6, the second semiconductor layers 114, functioning as channel regions, are shaped as parallel sheets extending between the source and drain regions. In some embodiments, the high-k dielectric layer 136 formed directly on and all over the exposed surfaces of the gate trenches G1 and G2 is located directly on the sidewalls of the gate spacers 124, and the high-k dielectric layer 136 formed directly on the exposed surfaces of the cavities C1 and C2 is located directly on the sidewalls of the lateral spacers 128. In some embodiments, the high-k dielectric layer 136 wraps around each of the second semiconductor layers 114.

In some embodiments, the high-k dielectric layer 136 corresponds to a gate dielectric layer of the transistor(s). The high-k dielectric layer 136 includes one or more layers of a dielectric material, such as hafnium dioxide (HfO₂), HfSiO, HfSiON, HfTaO, HfTiO, HfZrO, zirconium oxide, aluminum oxide, titanium oxide, hafnium dioxide-alumina alloy, other suitable high-k dielectric materials, and/or combinations thereof. The high-k dielectric layer 136 may be formed by CVD, ALD, or any suitable method. In one embodiment, the high-k dielectric layer 136 is formed using a highly conformal deposition process such as ALD in order to ensure the formation of a gate dielectric layer having a uniform thickness around each semiconductor nanosheet 114. In some embodiments, the thickness of the high-k dielectric layer 136 is in a range from about 0.5 nm to about 3 nm. It is understood that other materials and deposition processes may be used for the formation of the high-k dielectric layer 136, without departing from the scope of the present disclosure. The high-K gate dielectric layer 136 may include two or more sub-layers that include different high-k dielectric materials such as sublayers of HfO₂ and ZrO.

Referring to FIG. 6, after forming the high-k dielectric layer 136, a first metallic layer 138 is formed on the high-k dielectric layer 136 conformally covering the gate trenches G1 and G2 in the first and second regions RR1 and RR2. In some embodiments, the first metallic layer 138 not just covers the gate trenches G1 and G2 but also fills into the cavities C1 and C2. In some embodiments, within the cavities C1 and C2, the first metallic layer 138 is formed directly on the high-k dielectric layers 136 and substantially fills up the cavities (or voids) between the second semiconductor layers 114. In some embodiments, the first metallic layer 138 includes titanium (Ti), tungsten (W), vanadium (V), niobium (Nb), manganese (Mn), molybdenum (Mo), nitrides thereof or combinations thereof. In some embodiments, the first metallic layer 138 includes titanium nitride (TiN). In some embodiments, the first metallic layer 138 includes tungsten. For example, the first metallic layer 138 can be deposited using physical vapor deposition (PVD), ALD, CVD, or other suitable deposition processes. In some embodiments, the first metallic layer 138 includes a layer of titanium nitride (TiN) formed by CVD or ALD. In some embodiments, the first metallic layer 138 includes a layer of tungsten formed by PVD. In some embodiments, the first metallic layer 138 has a thickness between about 0.5 nm and about 10 nm.

After the formation of the high-k dielectric layer 136 and the first metallic layer 138, the cavities between the second semiconductor layers 114 in the sheet stacks 110T are filled, as shown in FIG. 6. In some embodiments, the sheet stacks 110T include the sheet stack 110T-1 in the first region RR1 and the sheet stack 110T-2 in the second region RR2. In some embodiments, the sheet stack 110T-1 includes the second semiconductor layers 114 (i.e. channel sheets), lateral spacers 128 located between the second semiconductor layers 114, and the high-k dielectric layer 136 and the first metallic layer 138 wrapping around the semiconductor layers 114, filling the cavities C1 and located between the lateral spacers 128 in the first region RR1. In some embodiments, the sheet stack 110T-2 includes the second semiconductor layers 114 (i.e. channel sheets), lateral spacers 128 located between the second semiconductor layers 114, and the high-k dielectric layer 136 and the first metallic layer 138 wrapping around the semiconductor layers 114, filling the cavities C2 and located between the lateral spacers 128 in the second region RR2.

FIG. 7 to FIG. 12 are schematic views of various stages in a manufacturing method of semiconductor devices in accordance with some embodiments of the disclosure. From FIG. 7 through FIG. 12, schematic cross-section views of semiconductor devices in a third region RR3, a fourth region RR4 and a fifth region RR5 at successive intermediate stages of processing are shown. Except for three regions are shown, the structure 70 illustrated in FIG. 7 is very similar to the structure 10 undergone the processes from FIG. 1 through FIG. 6, and similar elements, layers or parts may be labelled with the same or similar reference numbers.

As shown in FIG. 7, in some embodiments, the structure 70 includes a third region RR3, a fourth region RR4 and a fifth region RR5. Although the third region RR3, the fourth region RR4 and the fifth region RR5 are shown to be adjacent to one another, it is understood that only portions of the third region RR3, the fourth region RR4 and the fifth region RR5 are shown and the three regions are shown as side-by-side merely for illustration purposes. In some embodiments, the third region RR3, the fourth region RR4 and the fifth region RR5 may be spaced apart with other regions located there-between. In some embodiments, the third region RR3, the fourth region RR4 and the fifth region RR5 are located in the device region. In some embodiments, the third region RR3 is a short channel region, and the gate trench G3 has a channel width W3, the fourth region RR4 is a middle channel region, and the gate trench G4 has a channel width W4, and the fifth region RR5 is a long channel region, and the gate trench G5 has a channel width W5. In some embodiments, the channel width W3 of the narrowest gate trench G3 ranges from about 5 nm to about 20 nm, the channel width W4 of the gate trench G4 ranges from about 50 nm to about 80 nm, and the channel width W5 of the widest gate trench G5 ranges from about 100 nm to about 120 nm.

Referring to FIG. 7, as described in the previous embodiments, the high-k dielectric layer 136 and the first metallic layer 138 are sequentially formed over the gate spacers 124 and the interlayer dielectric layer 132 and over the gate trenches G3, G4 and G5. After the formation of the high-k dielectric layer 136 and the first metallic layer 138, in some embodiments, the formed sheet stacks 110T include the sheet stacks 110T-3, 110T-4 and 110T-5 respectively in the third region RR3, the fourth region RR4 and the fifth region RR5. In some embodiments, the sheet stacks 110T-3, 110T-4 and 110T-5 have substantially the same elements of the sheet stacks 110T-1 and 110T-2, including the semiconductor layers 114 (i.e. channel sheets), lateral spacers 128 located between the second semiconductor layers 114, and the high-k dielectric layer 136 and the first metallic layer 138 wrapping around the semiconductor layers 114 and located between the lateral spacers 128. Referring to FIG. 7, the high-k dielectric layer 136 and the first metallic layer 138 conformally cover the gate trenches G3, G4 and G5 and covers the gate spacers 124 and the sheet stacks 110T-3, 110T-4 and 110T-5. In some embodiments, the high-k dielectric layer 136 and the first metallic layer 138 are formed with satisfactory conformality and uniform thicknesses.

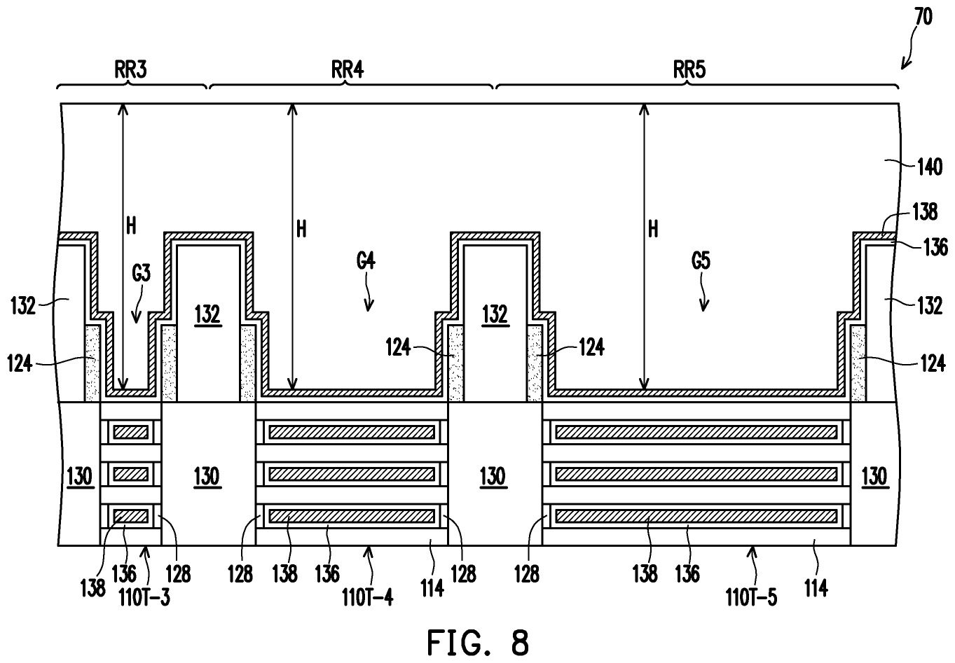

Referring to FIG. 8, a sacrificial layer 140 is globally formed over the interlayer dielectric layer 132 of the structure 70 and on the first metallic layer 138 and the high-k dielectric layer 136. In some embodiments, the first metallic layer 138 is fully covered by the sacrificial layer 140. In some embodiments, the sacrificial layer 140 on the first metallic layer 138 has substantially the same thickness/height H (measuring from the top surface of the sacrificial layer 140 to the first metallic layer 138 located at trench bottoms). In some embodiments, the pattern dependency of the sacrificial layer 140 is minimized, considering substantially the same height of the sacrificial layer 140 inside the gate trenches G3, G4 and G5 of very different widths.

In some embodiments, the sacrificial layer 140 is formed by depositing a sacrificial material thick enough to fill up the gate trenches G3, G4 and G5 and overlay the interlayer dielectric layer 132. In some embodiments, the material of the sacrificial layer 140 is or includes a metal oxide, such as aluminum oxide (AlOx), zinc oxide, tin oxide (SnOx), gallium oxide (GaOx), or a mixture thereof. In one embodiment, the material of the sacrificial layer 140 is aluminum oxide (e.g. Al₂O₃), and the material of the first metallic layer 138 is titanium nitride. In one embodiment, the material of the sacrificial layer 140 is aluminum oxide (e.g. Al₂O₃), and the material of the first metallic layer 138 is tungsten. In one embodiment, the material of the sacrificial layer 140 includes silicon. In some embodiments, the sacrificial layer 140 is formed by PVD such as sputtering. In some embodiments, the sacrificial layer 140 is formed by CVD. Although the gate trenches G3, G4 and G5 in the third, fourth and fifth regions RR3, RR4 and RR5 have different widths, the formed sacrificial layer 140 evenly covers the gate trenches G3, G4 and G5 with about the same height/thickness, and the sacrificial layer 140 is thick enough to cover the interlayer dielectric layer 132.

For forming filling materials into the trenches with very different widths or sizes, it is possible to have the filling materials filled in the wide trenches with a much lower thickness/height, and the variations in the thickness/height of the filling materials formed in the wide trenches and narrow trenches may cause incomplete coverage or filling of the trenches, which causes problems during etching or patterning. In some embodiments of this disclosure, a masking layer with good filling capability is formed and is filled into the trenches of very different widths or sizes with a substantially uniform thickness (or height). Compared with the organic bottom anti-reflection coating material, the sacrificial layer, functioning as the masking layer, covers various trenches (or patterns) with uniform coverage and equivalent thickness. Hence, a larger process window is provided and no extra mask is needed to compensate the uneven coverage.

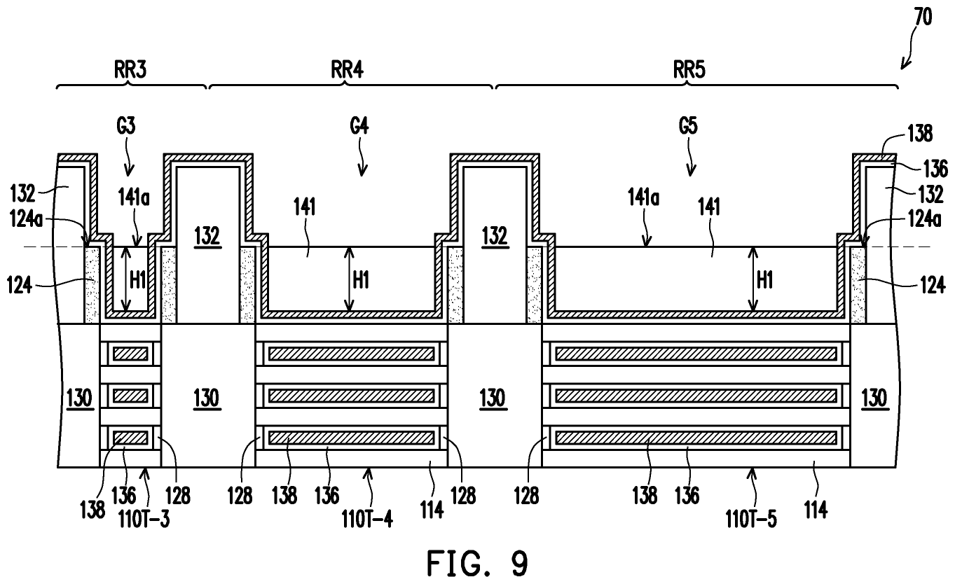

Referring to FIG. 9, a global etching process is performed to the structure 70 to etch back the sacrificial layer 140, and the sacrificial layer 140 is etched into a sacrificial masking layer 141 with a reduced height/thickness H1 (measuring from the top surface 141a of the sacrificial masking layer 141 to the first metallic layer 138 located at trench bottoms). In some embodiments, the top surface(s) 141a of the sacrificial masking layer(s) 141 is levelled with (at the same horizontal level with) the tops 124a of the gate spacers 124. That is, upper portions of the first metallic layer 138 are exposed after the global etching process while lower portions of the first metallic layer 138 are covered by the sacrificial masking layer 141. In some embodiments, the global etching process includes a wet etching process using an alkaline solution containing an amine. In one embodiment, the wet etching process is performed using an alkaline solution containing about 0.1-50 wt % (percentage by weight) of NH₄OH, tetramethyl ammonium hydroxide (TMAH) or a mixture thereof. In one embodiment, the material of the sacrificial layer 140 is aluminum oxide, and the wet etching process is performed using an alkaline solution containing about 0.1-50 wt % of NH₄OH. In some embodiments, the global etching process selectively etches off the material of the sacrificial layer 140 with respect to the material of the first metallic layer 138. For example, the wet etching process is time-controlled so that the sacrificial layer 140 is partially removed but not entirely removed to become the sacrificial masking layer 141 with a reduce height H1.

Referring to FIG. 9, in some embodiments, the top surface(s) 141a of the sacrificial masking layer(s) 141 is levelled with (at the same horizontal level with) the tops 124a of the gate spacers 124. In some other embodiments, the top surface(s) 141a of the sacrificial masking layer(s) 141 is slightly lower than the tops 124a of the gate spacers 124.

Due to high etching selectivity for the material of the sacrificial layer 140 with respect to the material of the first metallic layer 138, it is possible to precisely control the reduced height of the sacrificial masking layer 141 and minimize the height/thickness variations of the sacrificial masking layer 141 located in various trenches (i.e. minimal or almost zero thickness difference of the masking layer 141 between the narrowest trench and the widest trench).

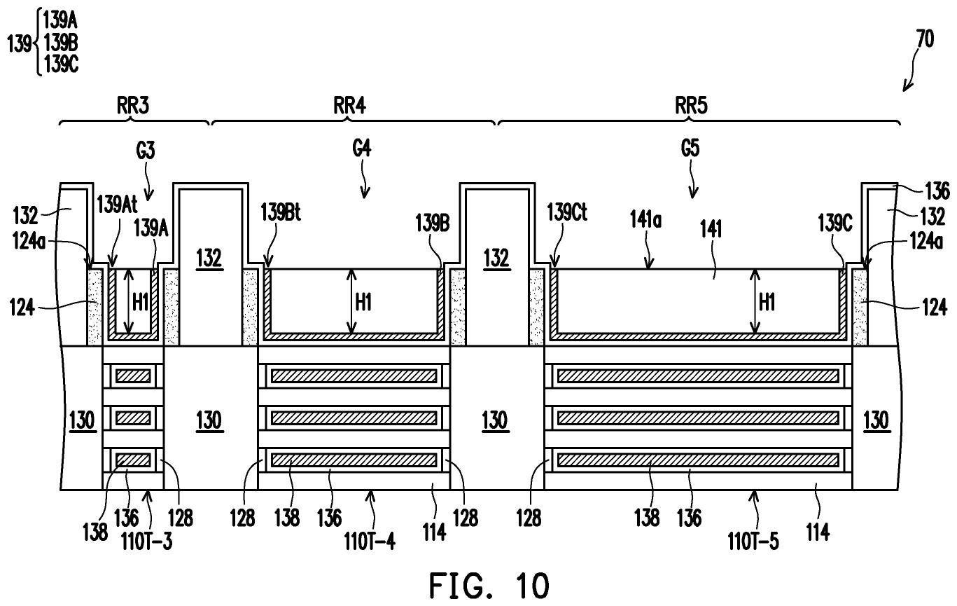

Referring to FIG. 10, in some embodiments, a pulling back process is performed to the first metallic layer 138 in the gate trenches G3, G4 and G5, and the first metallic layer 138 that is located in the gate trenches G3, G4 and G5 and uncovered by the sacrificial masking layer 141 is removed to become metallic patterns 139, including metallic patterns 139A, 139B and 139C respectively located in the gate trenches G3, G4 and G5. In some embodiments, as the sacrificial masking layer 141 is used as the etching mask for the pulling back process, the top surface(s) 141a of the sacrificial masking layer(s) 141 is levelled with (at the same horizontal level with) the tops 139At, 139Bt and 139Ct of the metallic patterns 139A, 139B and 139C. In some embodiments, as seen in FIG. 10, since the top surface(s) 141a of the sacrificial masking layer(s) 141 is levelled with the tops 124a of the gate spacers 124, the tops 139At, 139Bt and 139Ct are also levelled with the tops 124a of the spacers 124. In some other embodiments, as the top surface(s) 141a of the sacrificial masking layer(s) 141 is lower than the tops 124a of the gate spacers 124, the tops 139At, 139Bt and 139Ct are lower than the tops 124a of the spacers 124.

In some embodiments, the pulling back process includes a wet etching process using an oxidant-containing solution containing hydrogen peroxide (H₂O₂). In one embodiment, the wet etching process is performed using an acidic solution containing about 0.1-50 wt % (percentage by weight) of an acid such as HF, HCl, HBr, or any suitable organic acid and an oxidant such as hydrogen peroxide or ozone of a concentration ranging from 0.1 ppm to 107 ppm. In one embodiment, the material of the first metallic layer 138 is titanium nitride, and the wet etching process is performed using an acidic solution containing hydrogen peroxide. In one embodiment, the material of the first metallic layer 138 is tungsten, and the wet etching process is performed using an acidic solution containing ozone or hydrogen peroxide. In some embodiments, the pulling back process selectively etches off the material of the first metallic layer 138 with respect to the material of the sacrificial masking layer 141. Due to high etching selectivity for the material of the first metallic layer 138 with respect to the material of the sacrificial masking layer 141, it is possible to precisely control the height of the etched metallic patterns 139 and minimize the height/thickness variations of the metallic patterns 139 located in various trenches (i.e. minimal or almost zero thickness difference of the metallic patterns between the narrowest trench and the widest trench). For example, the wet etching process is time-controlled so that the uncovered portions of the first metallic layer 138 in the gate trenches G3, G4 and G5 are uniformly removed to become the metallic patterns 139A, 139B and 139C.

Due to the high selectivity, the first metallic layer 138 in the gate trenches G3, G4 and G5 are unvaryingly etched and the tops 139At, 139Bt and 139Ct of the metallic patterns 139A, 139B and 139C are levelled so that the metallic patterns 139A, 139B and 139C on the sidewalls of the gate trenches have the same extension height H1. That is, the metallic patterns 139A, 139B and 139C (i.e. the first metallic layer 138 that is located above the topmost semiconductor nanosheet(s) 114 and inside the gate trenches G3, G4 and G5) have the levelled tops 139At, 139Bt and 139Ct and the same extension height H1. In other words, no matter in the narrow gate trench G3, or in the wider gate trenches G4, G5, the tops 139At, 139Bt and 139Ct of the first metallic layer 138 are at the same level height (levelled with one another) and the first metallic layer 138 has the same extension distance H2 from the topmost semiconductor nanosheet(s) 114 to the tops 139At, 139Bt and 139Ct.

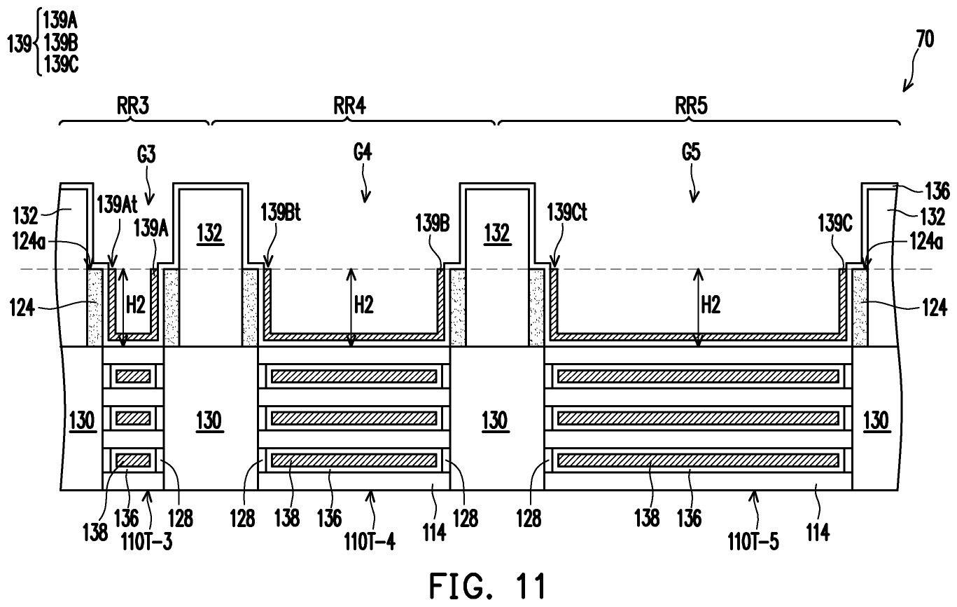

Referring to FIG. 11, a removal process is performed to remove the sacrificial masking layer 141. In some embodiments, the sacrificial masking layer 141 is completely removed from the gate trenches G3, G4 and G5 without removing or damaging the metallic patterns 139A, 139B and 139C. That is, after the removal of the sacrificial masking layer 141, voids are present and the metallic patterns 139A, 139B and 139C are exposed. In some embodiments, the removal process includes performing a wet etching process using an alkaline solution containing an amine. In one embodiment, the wet etching process is performed using an alkaline solution containing about 0.1-50 wt % (percentage by weight) of NH₄OH, tetramethyl ammonium hydroxide (TMAH) or a mixture thereof. In one embodiment, the material of the sacrificial masking layer 141 is aluminum oxide, and the wet etching process is performed using an alkaline solution containing about 0.1-50 wt % of NH₄OH. As the removal process selectively etching off the sacrificial masking layer 141, the surfaces of the metallic patterns 139A, 139B and 139C are intact and not damaged. Hence, the electrical properties of the transistors or devices are not degraded. In some alternative embodiments, the tops 139At, 139Bt and 139Ct of the metallic patterns 139A, 139B and 139C of the first metallic layer 138 are levelled with one another.

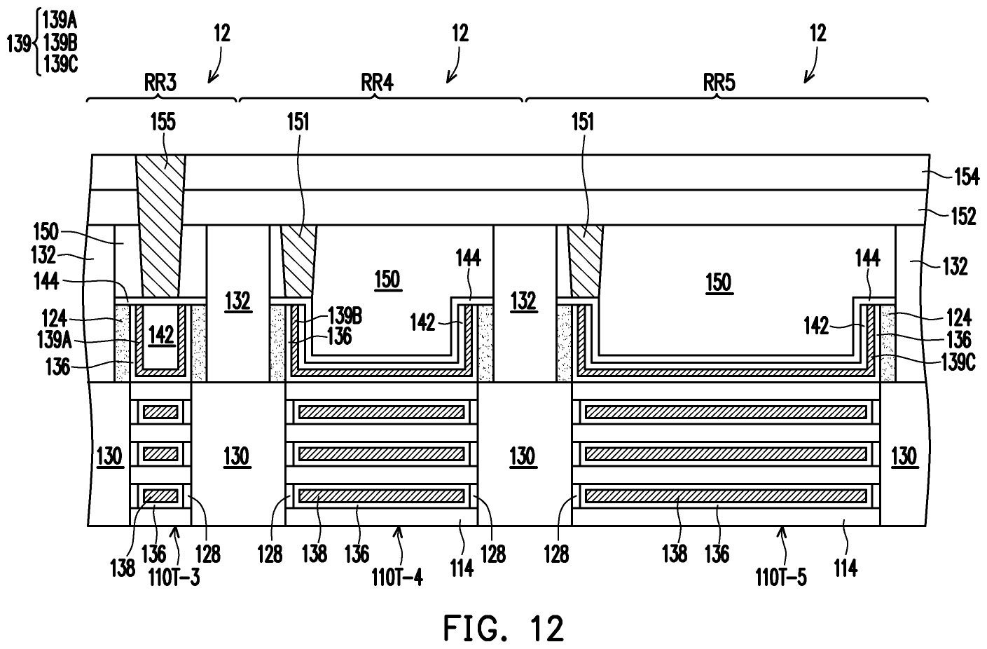

Referring to FIG. 12, after removing the sacrificial masking layer 141, a glue layer 142 is formed over gate trenches G3, G4 and G5 and on the metallic patterns 139A, 139B and 139C. In some embodiments, the glue layer 142 formed on the metallic pattern 139A fills up the void in the narrow gate trench G3 (in the short channel region RR3), while the glue layer 142 formed on the metallic patterns 139B and 139C does not fill up the voids but conformally covers and extends along the profiles of the metallic patterns 139B and 139C. In some embodiments, the glue layer 141 includes a metal nitride such as titanium nitride, tantalum nitride or a combination thereof. In some embodiments, the glue layer 142 is deposited using PVD, ALD, CVD, or other suitable deposition processes. In one embodiment, the glue layer 142 has a thickness ranging between about 2 nm and 20 nm. Later, in some embodiments, an etching back process is performed to remove the extra parts of the glue layer 142 and the high-k dielectric layer 136. In some embodiments, after the etching back process, the tops of the remained glue layer 142, the metallic patterns 139A, 139B and 139C and the remained high-k dielectric layer 136 are levelled (i.e. substantially at the same horizontal level). In some embodiments, the tops of the remained glue layer 142, the metallic patterns 139A, 139B and 139C and the remained high-k dielectric layer 136 are levelled with the tops 124a of the spacers 124.

Referring to FIG. 12, a second metallic layer 144 is formed over the gate trenches G3, G4 and G5 and on the remained glue layer 142, covering the remained glue layer 142, the metallic patterns 139A, 139B and 139C and the remained high-k dielectric layer 136. In some embodiments, the second metallic layer 144 covers the tops of the remained glue layer 142, the metallic pattern 139A and the remained high-k dielectric layer 136 in the narrow gate trench G3 (in the short channel region RR3). In some embodiments, the second metallic layer 144 conformally covers the remained glue layer 142, the metallic patterns 139B and 139C and the remained high-k dielectric layer 136 in the wider gate trenches G4 and G5 (in the middle and wide channel regions RR4 and RR5), and the second metallic layer 144 does not fill up the voids above the metallic patterns 139B and 139C but conformally extends along the profiles of the remained glue layer on the metallic patterns 139B and 139C. In some embodiments, the second metallic layer 144 includes tungsten or alloys thereof. In some embodiments, the second metallic layer 144 is deposited using PVD. In one embodiment, the second metallic layer 144 has a thickness ranging between about 0.5 nm and 5 nm.

In some embodiments, the glue layer 142 and the second metallic layer 144 and the first metallic layer 138 (including the metallic patterns 139) correspond to the gate electrode of the transistor, and the high-k dielectric layer 136 corresponds to the gate dielectric of the transistor. Although not explicit described herein, it is understood that the above described structure may further include a liner layer, an interfacial layer, a work function layer, or a combination thereof.

Later, referring to FIG. 12, in some embodiments, an inter-dielectric layer 150 is formed over the structure 70 covering the interlayer dielectric layer 132, filling up the voids and filling up the gate trenches G3, G4 and G5, and later contacts 151 are formed. The contacts 151 are formed in the inter-dielectric layer 150 and connect to the second metallic layer 144 in the fourth and fifth regions RR4 and RR5. In some embodiments, another inter-dielectric layer 152 and an insulating layer 154 are formed on the inter-dielectric layer 150. Later, in the third region RR3, at least one contact 155 is formed penetrating through the inter-dielectric layers 150 and 152 and the insulating layer 154 and the contact 155 connects to the second metallic layer 144. In some embodiments, the inter-dielectric layer 150 or 152 includes silicon nitride, silicon oxynitride, silicon carbide or a combination thereof. It is understood that the inter-dielectric layer 150 or 152 may include one or more dielectric materials or one or more dielectric layers. In some embodiments, the inter-dielectric layer 150 or 152 is formed to a suitable thickness by CVD such as plasma enhanced CVD (PECVD), PVD, ALD or other suitable methods. For example, an interlayer dielectric material layer (not shown) may be formed by PECVD and an etching or polishing process may be performed to reduce the thickness of the interlayer dielectric material layer until a desirable thickness to form the inter-dielectric layer 150 or 152. In some embodiments, the inter-dielectric layer 150 or 152 includes silicon nitride, and the insulating layer 154 includes silicon oxide, or one or more low-k dielectric materials. Examples of low-k dielectric materials include silicate glass such as phospho-silicate-glass (PSG) and boro-phospho-silicate-glass (BPSG), BLACK DIAMOND®, SILK®, hydrogen silsesquioxane (HSQ), fluorinated silicon oxide (SiOF), amorphous fluorinated carbon, parylene, BCB (bis-benzocyclobutene), flare, or a combination thereof. In some embodiments, the insulating layer 154 is formed using flowable CVD (FCVD), PECVD, spin-on coating, or other suitable methods.

As seen in FIG. 12, the contact 151 and 155 are shown with slant sidewalls. It is understood that the contact openings may be formed with substantially vertical sidewalls if feasible, and the number of the contacts is merely exemplary but not intended for limiting the scope of this disclosure. In some embodiments, the contacts 151 and 155 are formed of one or more metallic materials such as tungsten, cobalt, titanium, aluminum, copper, tantalum, nitrides thereof or alloys thereof. Optionally, the extra metallic material may be removed by performing a planarization process, an etching process, or other suitable processes. In some embodiments, the planarization process may include performing a CMP process. As seen in FIG. 12, the top surface of the layer 150 is substantially flush with and levelled with the top surfaces of the contacts 151, and the top surface of the insulating layer 154 is substantially flush with and levelled with the top surface of the contact 155.

In the previous embodiments, the first metallic layer 138 is shown to surround or partially surround the semiconductor nanosheets 114 along with the high-k dielectric layer 136, and in the figures the first metallic layer 138 is shown to fill the cavities and function as the around gate electrode. Although the subsequently formed glue layer 142 and the second metallic layer 144 in the subsequent figures may not be present in the cavities between semiconductor nanosheets 120. In some other embodiments, the glue layer 142 and the second metallic layer 144 may each be present in the cavities between the semiconductor nanosheets 114, depending on the dimensions of the transistor structure.

Referring to FIG. 12, the transistor 12 respectively in the regions RR3, RR4 and RR5 includes the semiconductor nanosheets 114 as the channel regions and the source and drain terminals 130 located at opposite sides of the semiconductor nanosheets 114. Also, the structure of the transistor 12 includes the high-k dielectric layer 136 as the gate dielectric and at least the metallic layer 138 wrapping around the semiconductor nanosheets 114 as the gate electrode. In some embodiments, the transistor 12 is referred to as a gate all around transistor, because the gate electrode (e.g. the metallic layer 138) surrounds the semiconductor nanosheets 114, and the semiconductor nanosheets 114 are physically separated from the metallic layer 138 by the gate dielectric made up of the high-k dielectric layer 136. When the transistor 12 is turned on by applying a voltage between the source and the gate electrode 138, current flows between the source and drain regions 130 through the semiconductor nanosheets 114 in the transistor 12.

In some embodiments, the transistors 12 respectively in the regions RR3, RR4 and RR5 includes contacts 155 and 151 in contact with the gate electrode (e.g. the metallic layer 144).

In the illustrated embodiments, the described methods and structures may be formed compatible with the current semiconductor manufacturing processes. In exemplary embodiments, the described methods and structures are formed during front-end-of-line (FEOL) processes. The illustrated structure of transistor(s) 12 may be a portion of integrated circuits. In some embodiments, the illustrated structure may include active devices such as thin film transistors, high voltage transistors, passive components, such as resistors, capacitors, inductors, fuses, and/or other suitable components. In some embodiments, additional steps may be provided before, during, and after the process steps depicted from FIG. 1 to FIG. 12, and some of the steps described above may be replaced or eliminated, for additional embodiments of the method.

As described above, the methods disclosed in the embodiments use the masking layer made of metal oxides such as aluminum oxide, through such masking layer used for metal pulling back process, the tops of the gate electrode layer (e.g. metallic layer 138) on the sidewalls of the gate spacers in trenches of very different widths are controlled to be located at the same level, so that the transistors located in different regions (e.g. short channel region (s) and long channel region(s)) can obtain the same satisfactory electrical properties. Further, due to the same level height of the tops of the gate electrode layer, minimum or no undesirable damage shall be caused to the metallic layer during the following process for forming contacts, which prevents the generation of unexpected leakage paths and avoids the yield loss.

Through using such masking layer, the surfaces of the gate electrode layer remain intact and are not damaged during the metal pulling back process and the removal of the masking layer, which improves the electrical performance of the transistors. Especially for the transistor(s) in the long channel region, the undesirable etching off of the gate electrode layer may deteriorate the electrical performance of the transistor(s) in the long channel region.

In the exemplary embodiments, the application of the metal oxide masking layer leads to even and equal etching off and metal pulling back of high selectivity for the device. Overall, the performance of the semiconductor device is enhanced.

In some embodiments of the present disclosure, a semiconductor device structure is described. The structure includes a substrate having a first region and a second region, first semiconductor channel sheets and second semiconductor channel sheets, first and second gate structure and source and drain regions. The first semiconductor channel sheets and the second semiconductor channel sheets are disposed over the substrate and respectively in the first region and the second region. The first semiconductor channel sheets have a first channel width shorter than a second channel width of the second semiconductor channel sheets. The first gate structure is disposed over and laterally surrounding the first semiconductor channel sheets. The first gate structure includes a first gate dielectric layer and a first metallic layer. The second gate structure is disposed over and laterally surrounding the second semiconductor channel sheets. The second gate structure includes a second gate dielectric layer and a second metallic layer. The source and drain regions are located beside the first semiconductor channel sheets and the second semiconductor channel sheets. Tops of the first metallic layer and the second metallic layer are located at a same horizontal level.

In some embodiments of the present disclosure, a method for forming a semiconductor device is described. After providing a substrate having a first region and a second region, a first stack in the first region and a second stack in the second region are formed. The first stack has first semiconductor sheets and first replaceable semiconductor sheets, and the second stack has second semiconductor sheets and second replaceable semiconductor sheets. A first dummy gate structure is formed on the first stack and a second dummy gate structure is formed on the second stack. The first dummy gate structure includes a first dummy gate and first gate spacers, and the second dummy gate structure includes a second dummy gate and second gate spacers. The first stack and the second stack are patterned respectively using the first dummy gate structure and the second dummy gate structure thereon as masks. The first dummy gate is removed to form a first gate trench of a first width and the second dummy gate is removed to form a second gate trench of the second width. The first width is shorter than the second width. A gate dielectric layer and a gate electrode layer are sequentially formed covering the first and second gate trenches and the first and second gate spacers. A sacrificial layer is formed on the gate electrode layer covering the first and second gate trenches and the first and second gate spacers. A global etching process is performed to partially remove the sacrificial layer to form a sacrificial masking layer inside the first and second gate trenches. The sacrificial masking layer in the first gate trench has a thickness substantially the same as a thickness of the sacrificial masking layer in the second gate trench. A pulling back process is performed to partially remove the gate electrode layer using the sacrificial masking layer as a mask. The sacrificial masking layer is removed. An inter-dielectric layer is formed filling up the first and second gate trenches.

In some embodiments of the present disclosure, a method for forming a semiconductor device is described. After providing a substrate having a first region and a second region, a first dummy gate structure is formed in the first region and a second dummy gate structure is formed in the second region. The first dummy gate structure includes a first dummy gate and first gate spacers, and the second dummy gate structure includes a second dummy gate and second gate spacers. The first dummy gate is removed to form a first gate trench of a first width and the second dummy gate is removed to form a second gate trench of the second width. The first width is shorter than the second width. A gate dielectric layer and a gate electrode layer are sequentially formed covering the first and second gate trenches and the first and second gate spacers. A sacrificial layer is formed on the gate electrode layer covering the first and second gate trenches and the first and second gate spacers. A global etching process is performed to partially remove the sacrificial layer to form a sacrificial masking layer inside the first and second gate trenches. The sacrificial masking layer in the first gate trench has a thickness substantially the same as a thickness of the sacrificial masking layer in the second gate trench. A pulling back process is performed to partially remove the gate electrode layer using the sacrificial masking layer as a mask. The sacrificial masking layer is removed. An inter-dielectric layer is formed filling up the first and second gate trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate having a first region and a second region;
first semiconductor channel sheets and second semiconductor channel sheets disposed over the substrate and respectively in the first region and the second region, wherein the first semiconductor channel sheets have a first channel width shorter than a second channel width of the second semiconductor channel sheets;
a first gate structure, disposed over and laterally surrounding the first semiconductor channel sheets, wherein the first gate structure includes a first gate dielectric layer and a first metallic layer;
a second gate structure, disposed over and laterally surrounding the second semiconductor channel sheets, wherein the second gate structure includes a second gate dielectric layer and a second metallic layer; and
source and drain regions, located beside the first semiconductor channel sheets and the second semiconductor channel sheets,
wherein tops of the first metallic layer and the second metallic layer are located at a same horizontal level.

2. The structure of claim 1, wherein the source and drain regions are located at opposite sides of the first semiconductor channel sheets and at opposite sides of the second semiconductor channel sheets.

3. The structure of claim 2, wherein the source and drain regions are epitaxy source and drain terminals.

4. The structure of claim 1, wherein the first gate dielectric layer and the second gate dielectric layer are made of the same material, and the first metallic layer and the second metallic layer are made of the same material.

5. The structure of claim 4, wherein each of the first metallic layer and the second metallic layer includes titanium nitride.

6. The structure of claim 4, wherein each of the first metallic layer and the second metallic layer includes tungsten.

7. The structure of claim 1, wherein the first semiconductor channel sheets and the second semiconductor channel sheets include silicon.

8. The structure of claim 1, wherein the first gate dielectric layer is located between the first metallic layer and the first semiconductor channel sheets, and the second gate dielectric layer is located between the second metallic layer and the second semiconductor channel sheets.

9. A method for forming a semiconductor device, comprising:
providing a substrate having a first region and a second region;
forming a first stack in the first region and a second stack in the second region, wherein the first stack has first semiconductor sheets and first replaceable semiconductor sheets, and the second stack has second semiconductor sheets and second replaceable semiconductor sheets;
forming a first dummy gate structure on the first stack and forming a second dummy gate structure on the second stack, wherein the first dummy gate structure includes a first dummy gate and first gate spacers, and the second dummy gate structure includes a second dummy gate and second gate spacers;
patterning the first stack and the second stack respectively using the first dummy gate structure and the second dummy gate structure thereon as masks;
removing the first dummy gate to form a first gate trench of a first width and removing the second dummy gate to form a second gate trench of the second width, wherein the first width is shorter than the second width;
forming a gate dielectric layer and a gate electrode layer sequentially covering the first and second gate trenches and the first and second gate spacers;
forming a sacrificial layer on the gate electrode layer covering the first and second gate trenches and the first and second gate spacers;
performing a global etching process to partially remove the sacrificial layer to form a sacrificial masking layer inside the first and second gate trenches, wherein the sacrificial masking layer in the first gate trench has a thickness substantially the same as a thickness of the sacrificial masking layer in the second gate trench;
performing a pulling back process to partially remove the gate electrode layer using the sacrificial masking layer as a mask;
removing the sacrificial masking layer; and
forming an inter-dielectric layer filling up the first and second gate trenches.

10. The method of claim 9, further comprising removing the first replaceable semiconductor sheets and the second replaceable semiconductor sheets to respectively form first cavities between the first semiconductor sheets and second cavities between the second semiconductor sheets during removing the first dummy gate and the second dummy gate.

11. The method of claim 9, further comprising removing the first replaceable semiconductor sheets and the second replaceable semiconductor sheets to respectively form first cavities between the first semiconductor sheets and second cavities between the second semiconductor sheets after removing the first dummy gate and the second dummy gate.

12. The method of claim 9, wherein performing a global etching process includes performing a wet etching process using an alkaline solution containing an amine.

13. The method of claim 9, wherein a material of the sacrificial layer includes aluminum oxide, and performing a global etching process includes performing a wet etching process using an alkaline solution containing about 0.1-50 wt % (percentage by weight) of NH₄OH, tetramethyl ammonium hydroxide (TMAH) or a mixture thereof.

14. The method of claim 9, wherein performing a pulling back process includes performing a wet etching process using an oxidant-containing solution.

15. The method of claim 9, wherein a material of the gate electrode layer includes titanium nitride, and performing a pulling back process includes performing a wet etching process using an oxidant-containing solution containing hydrogen peroxide.

16. The method of claim 9, wherein a material of the gate electrode layer includes tungsten, and performing a pulling back process includes performing a wet etching process using an oxidant-containing solution containing ozone.

17. A method for forming a semiconductor device, comprising:
providing a substrate having a first region and a second region;
forming a first dummy gate structure in the first region and forming a second dummy gate structure in the second region, wherein the first dummy gate structure includes a first dummy gate and first gate spacers, and the second dummy gate structure includes a second dummy gate and second gate spacers;
removing the first dummy gate to form a first gate trench of a first width and removing the second dummy gate to form a second gate trench of the second width, wherein the first width is shorter than the second width;
forming a metallic layer covering the first and second gate trenches and the first and second gate spacers;
forming a sacrificial layer on the metallic layer covering the first and second gate trenches and the first and second gate spacers;
performing a global etching process to partially remove the sacrificial layer to form a sacrificial masking layer inside the first and second gate trenches, wherein the sacrificial masking layer in the first gate trench has a thickness substantially the same as a thickness of the sacrificial masking layer in the second gate trench;
performing a pulling back process to partially remove the metallic layer using the sacrificial masking layer as a mask;
removing the sacrificial masking layer; and
forming a dielectric layer filling up the first and second gate trenches.

18. The method of claim 17, wherein performing a global etching process includes performing a wet etching process using an alkaline solution containing an amine.

19. The method of claim 17, wherein performing a pulling back process includes performing a wet etching process using an oxidant-containing solution.

20. The method of claim 17, wherein removing the sacrificial masking layer including performing a wet etching process using an alkaline solution containing an amine.
